(19) United States
(12) Patent Application Publication
(10) Pub. No.: US 2016/0333167 A1
(43) Pub. Date: Nov. 17, 2016

(54) ANISOTROPIC MAGNETODIELECTRIC POLYMER MATRIX COMPOSITES AND METHODS OF MANUFACTURE

(71) Applicant: Prime Photonics, LC, Blacksburg, VA (US)

(72) Inventors: David Todd Gray, Blacksburg, VA (US); David Berry, Christiansburg, VA (US)

(21) Appl. No.: 15/155,677

(22) Filed: May 16, 2016

Related U.S. Application Data
(60) Provisional application No. 62/162,132, filed on May 15, 2015.

(51) Int. Cl. C08K 3/38; H01L 41/20; H01F 1/01; H01B 3/12; C08K 3/08; C08K 3/20

(52) U.S. Cl. CPC C08K 3/38; C08K 3/08; C08K 3/20; H01F 1/01; H01B 3/12; H01L 41/20; C08K 2003/0862; C08K 2003/0856; C08K 2003/2206

(57) ABSTRACT

Polymer matrix composites normally consist of spherical or ellipsoidal reinforcement phases distributed randomly throughout the material. The spherical shape of the reinforcing materials reduces the effective electromagnetic properties of the reinforcement. Provided is a composite material which advantageously uses anisotropic electromagnetic properties of high aspect ratio loading using alignment to optimize the extrinsic effective electromagnetic property of the composite. Methods of manufacturing the composite are also described.

### CROSS-REFERENCE TO RELATED APPLICATIONS

The present application relies on the disclosure of and claims priority to and the benefit of the filing date of U.S. Provisional Application No. 62/162,132, filed on May 15, 2015, the disclosure of which is hereby incorporated by reference herein in its entirety.

### BACKGROUND OF THE INVENTION

1. Field of the Invention

The present invention relates to a class of electromagnetic materials wherein both complex impedance and index of refraction values are changed. Specifically, embodiments of the present invention relate to anisotropic, inhomogeneous electromagnetic polymer matrix composites and methods of manufacturing such composites.

2. Description of Related Art

Electromagnetic applications have suffered limitations due to the availability of materials that enable a wide range of control over both permeability and permittivity. Most single phase materials exhibit either magnetic or dielectric properties, but few monolithic materials exhibit both behaviors. Those materials that do have multiple ferroic orders tend to have characteristics of such low value so as to render them practically useless.

To address this issue, significant research has focused on developing composite materials consisting of magnetic, dielectric, or mixed reinforcement within a relatively inert matrix (most polymers). Polymer matrices typically require low temperature processing, enabling the use of a wide variety of reinforcements, from metastable metallic glass magnetic phases, to single crystal piezoceramics.

In the fabrication of most polymer matrix composites, spherical or ellipsoidal reinforcement phases are distributed randomly throughout the material. Random distribution of spheroids within the matrix is problematic in several aspects. The spherical shape of these reinforcing materials results in a depolarization field within the particle, reducing the effective electromagnetic properties of the reinforcement, and therefore, of the overall composite. One solution to counteract this reduction in extrinsic material property would be to increase the volume fraction of the electromagnetic phases within the bulk. Attempts to load materials above percolative limits are problematic, as high volume fractions reduce the effectiveness of the loading material.

Particles with high aspect ratio have anisotropic depolarization fields; along the axial direction, the extrinsic and intrinsic material properties are nearly identical. In the hard axis, depolarization fields approach unity—dramatically reducing the extrinsic material properties. Thus, random incorporation of high aspect ratio particles within the matrix will result in a certain portion of particles well aligned with external fields, while others will be aligned perpendicular. Under a truly random distribution, the effective material properties will reflect both high and low extrinsic averaging.

Related research attempts include those described in U.S. Pat. Nos. 4,006,479 and 2,610,250; yet there remains a need in the art for an effective solution to the limitations in the art described above.

### SUMMARY OF THE INVENTION

In embodiments, the present invention provides a method which enables the fabrication of a material with controlled electromagnetic properties that can be varied in three dimensions. The method enables additive manufacture of complex geometries and devices that are otherwise unable to be synthesized.

In brief, high aspect ratio dielectric particles, high aspect ratio magnetic particles, and/or conductive particles (which may or may not be high aspect ratio particles) are mixed with an appropriate matrix material. The materials are then processed through any mechanical means that induces net forces, preferably that are not isostatic, acting to soften the matrix, orient the particles, and, if needed, consolidate the matrix.

In one embodiment, the invention uses warm compaction to mechanically align the reinforcement of high aspect ratio particles within the matrix. When heated to below the melting point, matrix materials such as thermoplastic polymers will soften. Under the application of anisostatic pressure (e.g. uniaxial press, warm roller, or extrusion), the mechanical stresses will act on the high aspect ratio particles to induce a net orientation of the particles. The matrix material and reinforcement materials thus processed will result in a material with preferential alignment induced and controlled by a warm mechanical treatment procedure.

Embodiments also include compositions manufactured by the methods of the invention. The compositions are useful as composite materials for manufacturing a variety of electromagnetically active devices that have spatially varying electromagnetic properties.

Specific embodiments of the invention include a method for the fabrication of a composite material comprising: providing a plurality of components comprising a host matrix material and at least two of the following: (a) one or more high aspect ratio magnetic particles; (b) one or more high aspect ratio dielectric particles; (c) one or more conductive particles; and processing the components through a non-isostatic mechanical force that induces alignment of at least a portion of the high aspect ratio magnetic and/or dielectric particles within the host matrix material, wherein the host matrix material is heated to a temperature which induces softening of the host matrix material prior to application of the non-isostatic force.

Similarly, a method of fabricating a composite material is also included within the scope of the invention, the method comprising: providing a host matrix material; combining one or more high aspect ratio magnetic particles, one or more high aspect ratio dielectric particles, and one or more conductive particles with the host matrix material; and using a non-isostatic mechanical force and heat, aligning at least a portion of the high aspect ratio particles with one another within the host matrix material.

Included within the scope of embodiments of the invention is a composite material comprising: a host matrix material; one or more high aspect ratio magnetic particles; one or more high aspect ratio dielectric particles; and one or more conductive particles with the host matrix material; wherein at least a portion of the high aspect ratio particles are aligned with one another within the host matrix material.

Devices incorporating composites of the invention and/or incorporating materials made by methods of the invention include magnetoelectric sensors, inverse magnetoelectric sensors, magnetoelectric actuators, inverse magnetoelectric actuators, insulators, antennas or antenna substrates, an electromagnetic absorber, an electromagnetic steering element such as a lens, frequency selective surface, polarizer, or waveguide, or a radome or radome component.

In methods, composites, and/or devices of the invention the aspect ratio of the magnetic particles and dielectric particles can be greater than 1, greater than 2, 3 or greater, 4 or greater, 5 or greater, from 6-10 or greater, and so on including from 11-20 or greater.

In methods, composites, and/or devices of the invention the high aspect ratio particles can be aligned parallel with one another or can be aligned to within 5 degrees, 10 degrees, 15 degrees, 20 degrees, 25 degrees, 30 degrees, 40 degrees, 45 degrees, or 60 degrees off parallel with one another. The high aspect ratio particles can be aligned within the matrix to any desired degree. For example, 5%, 10%, 15%, 20%, 25%, 30%, 35%, 40%, 45%, 50%, 55%, 60%, 65%, 70%, 75%, 80%, 85%, 90%, 95%, or 100% of the high aspect ratio particles can be aligned parallel with one another or can be within the same range of deviation from parallel with one another. This degree of alignment can also be within one or more of the phases. For example, all phases in the material may be aligned to the same extent or one phase may be aligned to a certain extent while another phase is aligned to a different extent. In embodiments, a portion of or all of the particles can be in contact with or not in contact with other particles in the matrix, and/or a portion of or all of the particles can be in contact with or not in contact with the same type of particles in the matrix, and/or a portion of or all of the particles can be in contact with or not in contact with particles of a different type in the matrix.

The high aspect ratio particles can be aligned parallel with one another or can be aligned to within 5 degrees, 10 degrees, 15 degrees, 20 degrees, 25 degrees, 30 degrees, 40 degrees, 45 degrees, or 60 degrees off parallel with one another. In embodiments, the particles can be in contact with other particles in the matrix.

In methods, composites, and/or devices of the invention after processing of the host material and reinforcing materials, in embodiments at least 50%, 60%, 70%, 80%, or 90% or more of the high aspect ratio magnetic particles and/or high aspect ratio dielectric particles, and/or high aspect ratio conductive particles are aligned with other high aspect ratio particles within the host matrix material.

In methods, composites, and/or devices of the invention the host matrix material can be a thermoplastic polymer.

In methods, composites, and/or devices of the invention the one or more high aspect ratio magnetic particles, the one or more high aspect ratio dielectric particles, and/or the one or more conductive particles, including high aspect ratio conductive particles, can be provided, such as coated, in a core-shell configuration, such as before processing.

In methods, composites, and/or devices of the invention the one or more magnetic particles can comprise ferromagnetic particles, paramagnetic particles, diamagnetic particles, antiferromagnetic particles, ferrimagnetic particles, and/or the one or more magnetic particles can exhibit magnetostriction.

In methods, composites, and/or devices of the invention the one or more dielectric particles can comprise ferroelectric particles, paraelectric particles, piezoelectric particles, and/or pyroelectric particles.

In methods, composites, and/or devices of the invention the one or more conductive particles can comprise a metal, a semiconductor, a conductive ceramic, carbon, and/or high aspect ratio conductive particles, such as high aspect ratio carbon particles, single-walled nanotubes, multi-walled nanotubes, and/or graphene sheets.

The composites can be prepared using any non-isostatic mechanical force, including extrusion, rolling, and/or uniaxial compaction. In embodiments, the host matrix material can be heated to a temperature below the melting point of the host matrix material, such as prior to application of the non-isostatic force.

In embodiments, included is a composite material comprising a host matrix material and at least two of the following: (a) one or more high aspect ratio magnetic particles; (b) one or more high aspect ratio dielectric particles; (c) one or more conductive particles; wherein at least 10%, or 20%, or 30%, or 40%, or 50%, or 60%, or 70%, or 80%, or 90% of the high aspect ratio magnetic and/or dielectric particles are aligned within the host matrix material.

In methods, composites, and/or devices of the invention the composite material can be configured such that at least 95% of the high aspect ratio magnetic particles and/or high aspect ratio dielectric particles and/or high aspect ratio conductive particles are aligned within the host matrix material.

In embodiments, the composite material takes the form of a cylindrical filament.

In methods, composites, and/or devices of the invention the composite material can be configured to be capable of producing a magnetoelectric effect in response to an external magnetic field and/or capable of producing a magnetic moment in response to an external electrical field. In embodiments, a magnetic moment of the composite material is poled to provide orientation of magnetic domains and/or a net dielectric polarization is induced in the composite material.

### BRIEF DESCRIPTION OF THE DRAWINGS

The accompanying drawings illustrate certain aspects of embodiments of the present invention, and should not be used to limit the invention. Together with the written description the drawings serve to explain certain principles of the invention.

FIG. 1 is a diagram showing a composite having high aspect ratio magnetic and dielectric phases aligned within a matrix material according to an embodiment of the invention.

### DETAILED DESCRIPTION OF VARIOUS EMBODIMENTS OF THE INVENTION

Reference will now be made in detail to various exemplary embodiments of the invention. It is to be understood that the following discussion of exemplary embodiments is not intended as a limitation on the invention. Rather, the following discussion is provided to give the reader a more detailed understanding of certain aspects and features of the invention.

Embodiments of the invention provide methods for the fabrication of a composite material and composite materials produced by such methods. In one embodiment, the method comprises providing a plurality of components which include a host matrix material and at least one of the following: one or more high aspect ratio magnetic particles, one or more high aspect ratio dielectric particles, and one or more conductive particles (which may be low or high aspect ratio particles), and processing the components through a non-isostatic mechanical force that induces preferential alignment of the high aspect ratio particles. The high aspect ratio particles can have any elongated shape, including e.g., flakes, platelets, fibers, planar sheets, rods, whiskers, needles, ellipsoids, and/or filaments, including irregularly shaped particles with high aspect ratio such as jagged platelets, etc. As used herein, “high aspect ratio” refers to a particle possessing a minor axis (thickness) that is smaller than its average major axis (radius), i.e., an aspect ratio of greater than 1. Embodiments of the invention can include particles with an aspect ratio of greater than 1, 2, 3, 4, 5, 6, 7, 8, 9, 10, 15, 20, 25, 30, 35, 40, 45, 50, 55, 60, 65, 70, 75, 80, 85, 90, 95, 100, 200, 300, 400, 500, 600, 700, 800, 900, 1,000-5,000, or up to 10,000 or higher.

In embodiments, the host matrix material may be a thermoplastic polymer, such as polyethylene, polypropylene, polyvinyl chloride, polystyrene, acrylonitrile butadiene styrene, polybenzimidazole, acrylic, polytetrafluoroethylene and polyamide. In some embodiments, the host matrix material may be a blend of powdered precursors, a melt-cast polymer, or other precursor blend of polymer.

Additionally, in embodiments, any of the particles may be provided, such as coated, in a core-shell configuration before consolidation with the host matrix material. Core shell particles are those where the inner portion of the particle is of one material, and the outer portion is of another. Examples include, but are not limited to, a hard ferromagnetic core with a soft ferromagnetic shell, a magnetostrictive core with a piezoelectric shell, an antiferromagnetic core and a ferromagnetic shell. The materials used for the inner and outer portions of the particles can be of the same type or class of material and have a similar function, such as both the inner and outer materials being magnetic, or both the inner and outer materials being conductive, or both the inner and outer materials being dielectric. Likewise, the materials used for the inner and outer portions of the particles can be of different types or classes of materials and have different functions, such as the inner material being magnetic and the outer material being dielectric or vice versa, or the inner material being conductive and the outer material being dielectric or vice versa, or the inner material being magnetic and the outer material being conductive or vice versa.

Additionally, in embodiments of the invention, any of the particles may be provided in volume fractions that may range from 0 to 99% of the composition, such as from 0-10%, 10-20%, 10-25%, 5-30%, 10-30%, 15-30%, 5-25%, 10-40%, 15-45%, 25-40%, 20-50%, 30-50%, 40-60%, 5-95%, 35-65%, 45-55%, 50-65%, 50-80%, 40-75%, 40-80%, 50-75%, 10-50%, 20-80%, 60-80%, 75-95%, or 60-95% of the composition/composite based on volume. Thus, some embodiments of the invention may relate to compositions and methods that utilize a host matrix material and one or more high aspect ratio magnetic particles. Other embodiments of the invention may relate to compositions and methods that utilize a host matrix material and one or more high aspect ratio dielectric particles. Other embodiments of the invention may relate to compositions and methods that utilize a host matrix material and one or more conductive particles. Other embodiments of the invention may relate to compositions and methods that utilize a host matrix material and one or more high aspect ratio magnetic particles and one or more high aspect ratio dielectric particles. Other embodiments of the invention may relate to compositions and methods that utilize a host matrix material and one or more high aspect ratio magnetic particles and one or more conductive particles. Other embodiments of the invention may relate to compositions and methods that utilize a host matrix material and one or more high aspect ratio dielectric particles and one or more conductive particles. Other embodiments of the invention may relate to compositions and methods that utilize a host matrix material and one or more high aspect ratio magnetic, high aspect ratio dielectric, and conductive particles. Thus, compositions and methods of the invention relate to composites having a host matrix material and one or more high aspect ratio magnetic, high aspect ratio dielectric, and conductive particles in any combination, and at any volume fraction ranging from 0 to 99%.

Various embodiments of the invention provide that the one or more magnetic particles may have any magnetic property. For example, the one or more magnetic particles may include ferromagnetic, paramagnetic, diamagnetic, antiferromagnetic, or ferrimagnetic particles, or any combination thereof. Further, the one or more magnetic particles may exhibit magnetostriction. Non-limiting examples of ferromagnetic particles include those composed of nickel, iron, cobalt, gadolinium, neodymium, samarium, or their alloys. Non-limiting examples of paramagnetic particles include those composed of magnesium, molybdenum, lithium, and tantalum. Non-limiting examples of diamagnetic particles include those composed of bismuth, antimony, copper, silver, and gold. Non-limiting examples of antiferromagnetic particles include those composed of chromium, manganese, MnO, MnF₂, FeO, NiO, and CoO. Non-limiting examples of ferrimagnetic particles include those composed of magnetite (Fe₃O₄) and greigite (Fe₃S₄). In some embodiments, high aspect ratio particles are prepared by manufacturing nanowires composed of the above materials. Additional examples of magnetic particles that may be used in the composition are listed in Example 2.

Additionally, various embodiments of the invention provide that the more dielectric particles may have a variety of properties. For example, the one or more dielectric particles may be ferroelectric, pyroelectric, piezoelectric, or paraelectric particles, or any combination thereof. Non-limiting examples of particles with ferroelectric, pyroelectric, and/or piezoelectric properties include those composed of lead titanate (PbTiO₃), lead zirconate titanate (PZT), lead lanthanum zirconate titanate (PLZT), tourmaline, lithium sulfate monohydrate, and barium titanate. Non-limiting examples of paraelectric particles include those composed of SiO₂, Al₂O₃, and Ta₂O₅, and barium titanate. Additional non-limiting examples of dielectric materials include those composed of perovskite-related compounds, as well as metal oxides such as HfO₂, TiO₂, and ZrO₂. Additional non-limiting examples of piezoelectric materials that may be used in the composition are listed in Example 2. In some embodiments, high aspect ratio particles are prepared by manufacturing nanowires or crystals composed of the above materials.

Additionally, various embodiments of the invention provide that the one or more conductive particles may be composed of a variety of materials. The one or more particles may be electrically conductive, thermally conductive, or both electrically conductive and thermally conductive. For example, the one or more conductive particles may be or include a metal, or may be or include a semiconductor, or may be or include a conductive ceramic, or may be or include carbon. Non-limiting examples of the metallic particles include silver, copper, gold, aluminum, molybdenum, zinc, lithium, tungsten, brass, nickel, iron, palladium, platinum, tin, bronze, lead, titanium, and the like. Non-limiting examples of the semiconductor materials include germanium, silicon, gallium arsenide, silicon carbide, gallium nitride, gallium phosphide, cadmium sulfide, and lead sulfide. In some embodiments, the conductive particles are high aspect ratio particles. In other embodiments, the conductive particles are low aspect ratio particles. Further, when the conductive materials include carbon, the conductive particles may be high aspect ratio carbon particles, such as single walled nanotubes or multi-walled nanotubes. Conceivably, the carbon particles may also be graphene sheets. Additionally, the conductive particles may be magnetic, non-magnetic, dielectric, or non-dielectric.

The high aspect ratio particle components of the composite may be nanowires, powders, flakes, or any combination. For example, nanowires of the materials of the composite can be produced using techniques such as suspension, electrochemical deposition, vapor deposition, and vapor-liquid-solid growth. Aspect ratio may be quantified by way of image analysis software applied to microscopic images. High aspect ratio particles such as nanowires are available from Sigma Technologies Intl, LLC (Tucson Ariz.), NANOCOMPOSIX, INC. (San Diego, Calif.), ACS Material, LLC (Medford, Mass.), US Research Nanomaterials, Inc. (Houston, Tex.), and Sigma-Aldrich (St. Louis, Mo.) for example.

In the method of preparing the composite, a variety of non-isostatic mechanical forces may be used, such as extrusion, rolling, or uniaxial compaction. As a result of preparing the composite, it is believed that both mechanical coupling and thermal coupling between magnetostrictive and piezoelectric orders is achieved through the matrix material. In embodiments, the non-isostatic mechanical forces are performed at elevated temperatures such as up to and just below the melting point of the particles of the matrix such that the matrix softens during application of the mechanical forces. A skilled artisan will recognize that the exact temperatures used in the process will depend on the composition of the matrix materials. Preferred are temperatures approaching but below the melting the point of the matrix material.

Further, the methods of preparing the composite may include steps to assure distribution of the particles in the matrix material, such as mixing by way of a blender. Additionally, a skilled artisan will recognize that the methods of preparing the composite can be scaled up to a quantity appropriate for industrial manufacture using equipment such as extruders, rollers, and uniaxial die presses, and the like.

Additional embodiments of the invention provide for a composite material manufactured according to any of the methods of the invention. In embodiments, the composite material may include a host matrix material and one or more components comprising one or more high aspect ratio magnetic particles, one or more high aspect ratio dielectric particles, and one or more conductive particles in any combination. The one or more high aspect ratio magnetic particles, one or more high aspect ratio dielectric particles, and one or more conductive particles may be those described above. In embodiments, at least a portion of the high aspect ratio magnetic and/or dielectric particles are aligned in the composite. In some embodiments, the composite material can take the form of a cylindrical filament. Additionally, in some embodiments, the composite material is capable of producing a magnetoelectric effect in response to an external magnetic field. Additionally, in some embodiments, the composite material is capable of producing a magnetic moment in response to an external electrical field. The magnetic moment of the composite material may be poled to provide orientation of magnetic domains. Additionally, a net dielectric polarization may be induced in the composite material.

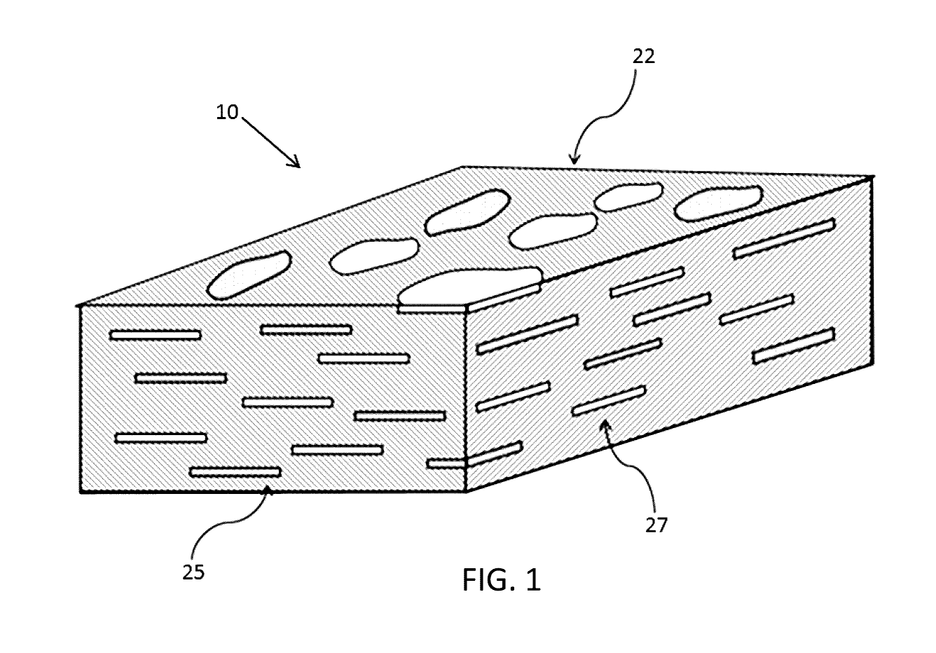

FIG. 1 shows a composite material 10 according to an embodiment of the invention. As shown in FIG. 1, high aspect ratio magnetic 25 and dielectric 27 phases are aligned in the matrix 22 of the composite material.

As can be seen in FIG. 1, the method can produce composites in which substantially all of the magnetic and dielectric particles are aligned. However, in other embodiments, not all of the magnetic and dielectric particles are aligned. Preferentially, at least a majority, such as more than 50%, 55%, 60%, 65%, 70%, 75%, 80%, 85%, 90%, 95%, 96%, 97%, 98%, 99%, or more of the magnetic and/or dielectric particles are aligned in the composite. However, in some embodiments, less than a majority, such as 5%, 10%, 15%, 20%, 25%, 30%, 35%, 40%, or 45% of the magnetic and/or dielectric particles are aligned in the composite. According to this disclosure, the terms aligned, align, aligning (and related terms) with respect to two or more particles is intended to mean that the two or more particles are aligned substantially parallel in orientation longitudinally (i.e. along their major axes). The terms aligned, align, aligning (and related terms) may include some degree of deviation from parallel between two particles, such as from 1, 2, 3, 4, 5, 6, 7, 8, 9, 10, 15, 20, 25, 30, 40, 45, 50, 65, 80, or 90 degrees.

Additional embodiments of the invention provide for a device comprising any composite material disclosed herein. In embodiments, the device can be a magnetoelectric sensor, an inverse magnetoelectric sensor, magnetoelectric actuator, an inverse magnetoelectric actuator, or an insulator.

The following Examples describe preferred embodiments of the invention. However, they are intended to be illustrative and should not be considered to limit the scope of the invention in any way. While it is apparent that the illustrative embodiments of the invention disclosed herein fulfill the objectives stated above, it is appreciated that numerous modifications and other embodiments may be devised by those skilled in the art.

### EXAMPLE 1

A powdered blend of a polymer matrix material, a magnetic flake material with high aspect ratio and a dielectric flake material with a high aspect ratio is prepared. The electromagnetic properties of the powder blend can be tuned for wave guiding applications (matched permeability and permittivity, controlled index of refraction, and low-loss), or as an absorber (tuned loss and complex impedance response) through selection of the composition of the reinforcement materials. The isotropy of the final material can be controlled through selection of reinforcement form factor between rod and flake.

The powder blend and high aspect ratio materials are consolidated through warm extrusion to provide preferential alignment of the magnetic and electric flakes within the polymer matrix. In this implementation, the extrusion takes the form of a cylindrical filament that can then be used as the precursor feedstock material for additive manufacture through fused deposition modeling. The filament will have isotropic material properties, with higher permeability and permittivity along the axial direction of the filament. Use of an anisotropic magnetodielectric filament will enable the additive manufacture of complex antenna structures and frequency selective surfaces that have spatially varying electromagnetic properties.

For example, a slab of material manufactured through fused deposition modeling of the anisotropic filaments could show high permeability, high permittivity, and low loss along one direction of the slab. Along the other two orthogonal directions, the material could show lower permeability, lower permittivity, and higher loss. The permeability and permittivity can be tuned independently such the overall impedance of the device remains matched to air, but the index of refraction shows a strong anisotropy. Such properties would allow for manufacture of high efficiency waveguides or antennas with controlled sidelobe radiation patterns. These structures would have low reflectance, and an orientation-dependent electrical size.

### EXAMPLE 2

A magnetostrictive flake (e.g. CoFeSiB metallic glass, permalloy (a nickel-iron magnetic alloy), Terfenol-D an alloy comprised of Terbium, Dysprosium and Iron, available from ETREMA Products, Inc. (Ames, Iowa)), Galfenol (a magnetostrictive alloy comprised primarily of the elements iron (Fe) and gallium (Ga), also available from ETREMA Products, Inc. (Ames, Iowa))) and a piezoelectric flake (e.g. BaTiO3, lead zirconate titanate (PZT), lead magnesium niobate-lead titanate (PMN-PT), etc) can both be incorporated. Upon warm consolidation, the particles are aligned to within a desired tolerance, and mechanical coupling between the ferroic orders is provided through the matrix. A device may be manufactured from this material, and one or both of the ferroic phases poled through application of an external field. The device will then respond to an external magnetic field by producing a charge (magnetoelectric effect), or to an external electric field by producing a magnetic moment (inverse magnetoelectric effect). The device can act as a sensor (either vector or planar, depending on the reinforcement for factor), or as an actuator. Furthermore, when the constituent phases have non-linear properties, application of a DC bias field will enable tuning of the overall electromagnetic properties of the resulting structure. This enables the fabrication of antennas whose center frequency can be tuned electronically.

### EXAMPLE 3

Polymeric insulators with elevated breakdown strength can be fabricated by incorporating dielectric flakes and conductive spheroids into a polymer matrix. In the direction perpendicular to the dielectric alignment, the dielectric material will exhibit a lower effective dielectric than the matrix, reducing the electric field within the matrix. Furthermore, random distribution of the particles will present a torturous path for electrical treeing, increasing breakdown strength.

The present invention has been described with reference to particular embodiments having various features. In light of the disclosure provided above, it will be apparent to those skilled in the art that various modifications and variations can be made in the practice of the present invention without departing from the scope or spirit of the invention. One skilled in the art will recognize that the disclosed features may be used singularly, in any combination, or omitted based on the requirements and specifications of a given application or design. When an embodiment refers to “comprising” certain features, it is to be understood that the embodiments can alternatively “consist of” or “consist essentially of” any one or more of the features. Other embodiments of the invention will be apparent to those skilled in the art from consideration of the specification and practice of the invention.

It is noted in particular that where a range of values is provided in this specification, each value between the upper and lower limits of that range is also specifically disclosed. The upper and lower limits of these smaller ranges may independently be included or excluded in the range as well. The singular forms “a,” “an,” and “the” include plural referents unless the context clearly dictates otherwise. It is intended that the specification and examples be considered as exemplary in nature and that variations that do not depart from the essence of the invention fall within the scope of the invention. Further, all of the references cited in this disclosure including issued patents and published patent applications are each individually incorporated by reference herein in their entireties and as such are intended to provide an efficient way of supplementing the enabling disclosure of this invention as well as provide background detailing the level of ordinary skill in the art.

1. A method of fabricating a composite material, the method comprising:
providing a polymer host matrix material;
combining one or more of the following with the host matrix material:
a) one or more types of high aspect ratio magnetic particles; and/or
b) one or more types of high aspect ratio dielectric particles;
using a non-isostatic mechanical force and optionally heat, aligning at least a portion of the high aspect ratio particles within the host matrix material to fabricate a composite material, wherein at least a portion of the high aspect ratio particles are aligned within the host matrix material in a manner to provide the composite material with a target level of permeability, permittivity, or dielectric loss.

2. The method of claim 1, wherein the non-isostatic mechanical force is extrusion, rolling, or uniaxial compaction.

3. The method of claim 1, wherein the aligning provides for at least a portion of the high aspect ratio particles to be aligned parallel with one another or aligned to within 30 degrees of parallel with one another.

4. The method of claim 3, wherein at least 50% of the high aspect ratio particles of at least one phase of the composite material are aligned with one another within that phase.

5. The method of claim 1, wherein the aspect ratio of the magnetic particles and/or of the dielectric particles is 3 or greater.

6. The method of claim 1, further comprising combining a plurality of conductive particles with the host matrix material.

7. A polymer matrix composite material comprising:
a polymer host matrix material comprising one or more of the following:
a) one or more types of high aspect ratio magnetic particles;
b) one or more types of high aspect ratio dielectric particles; and/or
wherein the high aspect ratio particles are aligned within the host matrix material in a manner to impart the composite material with one or more of higher permeability, higher permittivity, or lower dielectric loss along a first axis of the composite material in comparison to permeability, permittivity, or dielectric loss along a second and third axis of the composite material, wherein the second and third axis are orthogonal to the first axis.

8. The method of claim 7, further comprising combining a plurality of conductive particles with the host matrix material.

9. The composite material of claim 7, wherein at least a portion of the high aspect ratio particles are aligned parallel with one another or are aligned to within 30 degrees of parallel with one another.

10. The composite material of claim 7, wherein at least 50% of the high aspect ratio particles of at least one phase of the composite material are aligned with one another within that phase.

11. The composite material of claim 7, wherein the aspect ratio of the magnetic particles and/or of the dielectric particles is 3 or greater.

12. The composite material of claim 7, wherein the host matrix material is a thermopolymer.

13. The composite material of claim 7, wherein any of the particles are provided in a core-shell configuration.

14. The composite material of claim 7, wherein the high aspect ratio magnetic particles are chosen from ferromagnetic particles, paramagnetic particles, diamagnetic particles, antiferromagnetic particles, ferrimagnetic particles and/or exhibit magnetostriction.

15. The composite material of claim 7, wherein the high aspect ratio dielectric particles are chosen from ferroelectric particles, paraelectric particles, piezoelectric particles, or pyroelectric particles.

16. The composite material of claim 7, wherein the conductive particles comprise metal, a semiconductor, a conductive ceramic, carbon, high aspect ratio conductive particles, single-walled nanotubes, multi-walled nanotubes, or graphene sheets.

17. The composite material of claim 7, which is in the form of a cylindrical filament.

18. The composite material of claim 7, wherein the high aspect ratio particles are aligned within the host matrix material in a manner to impart the composite material with an ability to produce a magnetoelectric effect in response to an external magnetic field.

19. The composite material of claim 7, wherein the high aspect ratio particles are aligned within the host matrix material in a manner to impart the composite material with an ability to produce a magnetic moment in response to an external electrical field.

20. The composite material of claim 7, wherein the high aspect ratio particles are aligned within the host matrix material in a manner to impart the composite material with a magnetic moment that is poled to provide orientation of magnetic domains.

21. The composite material of claim 7, wherein the high aspect ratio particles are aligned within the host matrix material in a manner to impart the composite material with a net dielectric polarization.

22. The composite material of claim 7, wherein the composite material exhibits one or more of higher permeability, higher permittivity, and lower dielectric loss along a first axis of the composite material in comparison to permeability, permittivity, and dielectric loss along a second and third axis of the composite material, wherein the second and third axis are orthogonal to the first axis.
